(19) United States
(12) Patent Application Publication
(10) Pub. No.: US 2025/0357194 A1
(43) Pub. Date: Nov. 20, 2025

(54) INTERCONNECT STRUCTURE WITH HIGH THERMAL CONDUCTIVITY AND LOW PARASITIC CAPACITANCE

(71) Applicant: Taiwan Semiconductor Manufacturing Company, Ltd., Hsin-Chu (TW)

(72) Inventors: Ting-Ya Lo, Hsinchu (TW); Cheng-Chin Lee, Taipei City (TW); Shao-Kuan Lee, Kaohsiung City (TW); Hsin-Yen Huang, New Taipei City (TW); Hsiao-Kang Chang, Hsinchu City (TW)

(21) Appl. No.: 19/285,638

(22) Filed: Jul. 30, 2025

Related U.S. Application Data
(63) Continuation of application No. 18/612,386, filed on Mar. 21, 2024.
(60) Provisional application No. 63/593,700, filed on Oct. 27, 2023.

(51) Int. Cl. H01L 21/768; H01L 23/528; H01L 23/532

(52) U.S. Cl. CPC H01L 21/7682; H01L 21/76832; H01L 21/76834; H01L 21/76885; H01L 23/5283; H01L 23/53295; H01L 23/53242

(57) ABSTRACT

Semiconductor structures and methods of forming the same are provided. An exemplary semiconductor structure includes a conductive via embedded in a first dielectric layer, a second dielectric layer over the first dielectric layer, a first metal line embedded in the second dielectric layer and in electrical coupling with the conductive via, and a second metal line embedded in the second dielectric layer and separated from the first metal line by a dielectric structure. A top surface of the dielectric structure is coplanar with top surfaces of the first and second metal lines. The dielectric structure includes a capping layer extending between opposing sidewalls of the first and second metal lines, a thermal conductive layer over the capping layer, and an air gap between the capping layer and the thermal conductive layer.

### PRIORITY DATA

The is a continuation application of U.S. patent application Ser. No. 18/612,386, filed Mar. 21, 2024, which claims benefit of U.S. Provisional Application No. 63/593,700, filed Oct. 27, 2023, each of which is herein incorporated by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As device dimensions continue to shrink, performance of back-end-of-line (BEOL) interconnect structures are subject to higher requirements. For example, when distance between two adjacent conductive features reduces to meet design requirements of smaller technology nodes, high parasitic capacitance may lead to lower device speed (e.g., RC delays). Low dielectric constant (low-k) materials have been incorporated into interconnect structures to lower parasitic capacitance. While the low-k materials serve their purposes of lowering parasitic capacitance, their inadequate thermal conductivities present challenges in dissipation of heat from front-end-of-line (FEOL) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary cross-sectional view of an exemplary semiconductor structure, according to one or more aspects of the present disclosure.

FIG. 2 is a flowchart of a method for forming interconnect layers of the semiconductor structure, according to one or more aspects of the present disclosure.

FIGS. 3, 4, 5, 6, 7, 8, 9, 10, 11, 12, 14, 15, 16, 17, 18, 19, 20, 21, 22, 23, 24, 25, 26, 27, 28, and 29 are fragmentary cross-sectional views of a workpiece at various stages of fabrication according to the method in FIG. 2, according to one or more aspects of the present disclosure.

FIG. 13 is a fragmentary top view of the workpiece shown in FIG. 12, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art.

As the front-end-of-line (FEOL) devices becomes smaller, the back-end-of-line (BEOL) interconnect structures play a greater role in keeping up with the power, performance and area requirements. The BEOL interconnect structures may include low-k dielectric material to keep the parasitic capacitance low. In general, low-k dielectric materials exhibit thermal conductivities lower than those of high-k dielectric materials, metals or semiconductor materials. The low thermal conductivities of low-k dielectric materials hinder their ability to effectively dissipate heat generated by the FEOL devices. In addition, packing all conductive features on one side of a substrate is becoming more and more challenging. To case the packing density, routing features may be partially moved to a backside of the substrate. Such routing features may include backside power rails and/or backside contacts. Introducing backside routing features further aggravates thermal accumulation due to an increased distance between devices and a heat sink. The industry scrambles to find a solution of interconnect structures to achieve high thermal conductivity while keeping a low parasitic capacitance.

The present disclosure provides methods of forming a dielectric structure disposed between adjacent metal lines for heat dissipation and parasitic capacitance reduction. In an example process, a metal layer is patterned to form metal lines with trenches therebetween. A sacrificial layer is then deposited to fill lower portions of the trenches. A sustaining layer is deposited on the sacrificial layer. After forming the sustaining layer, a thermal treatment is performed to selectively remove the sacrificial layer, thereby forming air gaps between the patterned metal lines. After the removal of the sacrificial layer, a high-kappa non-conductive material layer is formed on the sustaining layer to fill upper portions of the trenches. The high-kappa non-conductive material layer, which are formed of materials with good thermal conductivities, facilitate heat dissipation. The air gaps between metal lines help keep a low capacitance.

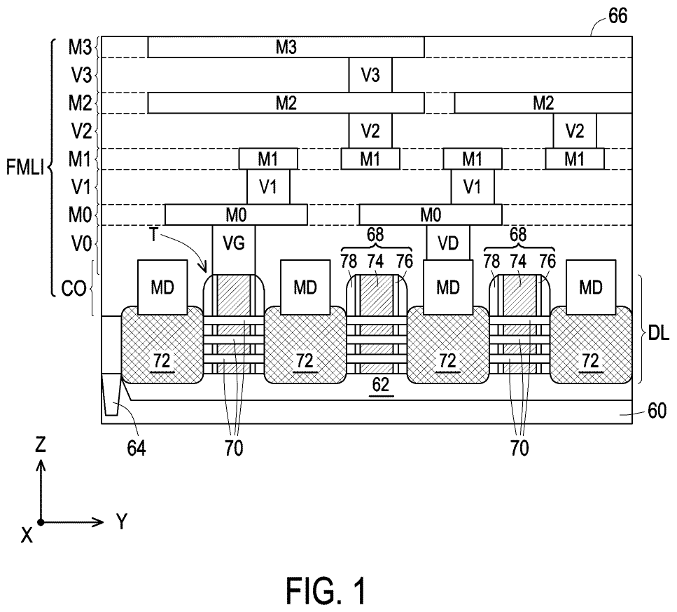

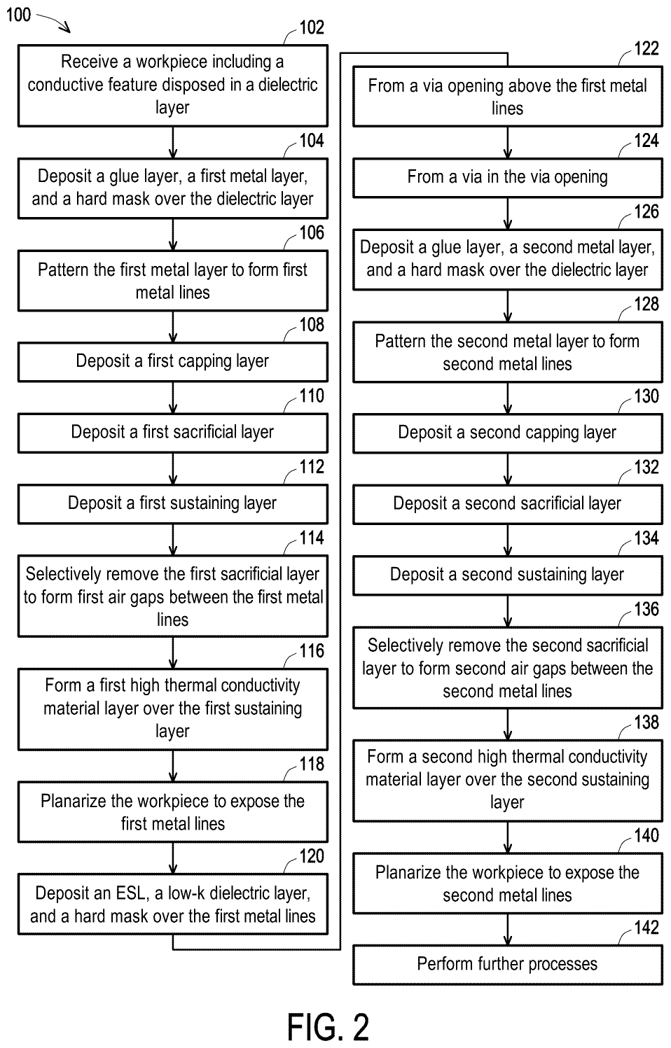

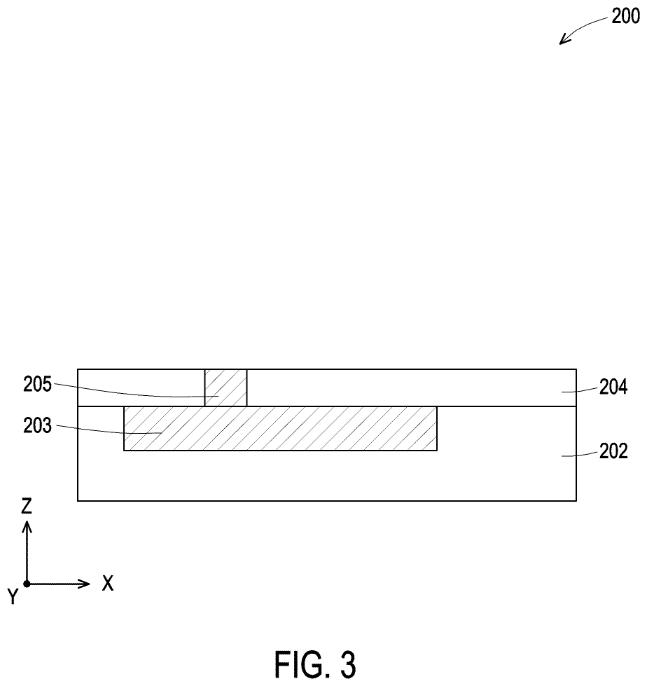

The various aspects of the present disclosure will now be described in more detail with reference to the figures. In that regard, FIG. 1 is a fragmentary cross-sectional view of an exemplary semiconductor structure, according to one or more aspects of the present disclosure. FIG. 2 is a flowchart illustrating method 100 for forming interconnect layers of the semiconductor structure, according to one or more aspects of the present disclosure. Method 100 is merely an example and are not intended to limit the present disclosure to what is explicitly illustrated in method 100. Additional steps may be provided before, during, and after method 100, and some steps described can be replaced, eliminated, or moved around for additional embodiments of method 100. Not all steps are described herein in detail for reasons of simplicity. Method 100 is described below in conjunction with FIGS. 3-29, which are fragmentary top or cross-sectional views of a workpiece 200 at different stages of fabrication according to embodiments of method 100. Because the workpiece 200 will be fabricated into a semiconductor structure upon conclusion of the fabrication processes, the workpiece 200 may be referred to as a semiconductor structure 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

FIG. 1 is a fragmentary diagrammatic cross-sectional view of various layers (levels) that can be fabricated over a semiconductor substrate (or wafer) 60 to form a portion of a semiconductor structure, according to various aspects of the present disclosure. As represented in FIG. 1, the various layers include a device layer DL and a frontside multilayer interconnect structure FMLI disposed over the device layer DL. In various embodiments, the structure may also include a backside multilayer interconnect structure BMLI disposed under the device layer DL. The backside multilayer interconnect structure BMLI may be similar to the frontside multilayer interconnect structure FMLI.

Device layer DL includes devices (e.g., transistors, resistors, capacitors, and/or inductors) and/or device components (e.g., doped wells, gate structures, and/or source/drain features). In embodiments represented by FIG. 1, the device layer DL includes substrate 60, doped regions 62 (e.g., n-wells and/or p-wells) disposed in substrate 60, isolation feature 64, and transistors T. In the depicted embodiment, transistors T include suspended channel layers 70 and gate structures 68 disposed between source/drain features 72, where gate structures 68 wrap and/or surround suspended channel layers 70. Each gate structure 68 has a metal gate stack formed from a gate electrode 74 disposed over a gate dielectric layer 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements. Each of the multilayer interconnect structures FMLI and BMLI may include one or more interconnect layers. In the depicted embodiment, the frontside multilayer interconnect structure FMLI includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the frontside multilayer interconnect structure FMLI with N as an integer ranging from 1 to 10. Each level of the frontside multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the frontside multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In embodiments represented by FIG. 1, the CO level includes source/drain contacts MD disposed in the dielectric structure 66. The source/drain contacts MD may be formed on and in contact with silicide layers disposed directly on the source/drain features 72. The V0 level includes gate vias VG disposed on the gate structures 68 and source/drain contact vias VD disposed on the source/drain contacts MD, where gate vias VG connect gate structures 68 to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines. FIG. 1 has been simplified for the sake of clarity to better understand the inventive concepts of the present disclosure.

Referring to FIGS. 2 and 3, method 100 includes a block 102 where a workpiece 200 is received (or provided). The workpiece 200 includes a substrate 202. In some embodiments, the substrate 202 includes silicon. Alternatively, the substrate 202 may include other elementary semiconductor such as germanium in accordance with some embodiments. In some embodiments, the substrate 202 additionally or alternatively includes a compound semiconductor such as silicon carbide, gallium arsenic, indium arsenide, and indium phosphide. In some embodiments, the substrate 202 includes an alloy semiconductor such as silicon germanium, silicon germanium carbide, gallium arsenic phosphide, and gallium indium phosphide.

In some embodiments, the substrate 202 includes a semiconductor-on-insulator (SOI) structure. For example, the substrate may include a buried oxide (BOX) layer formed by a process such as separation by implanted oxygen (SIMOX). In various embodiments, the substrate 202 includes various p-type doped regions and/or n-type doped regions, such as p-type wells, n-type wells, p-type source/drain features and/or n-type source/drain features, formed by a process such as ion implantation and/or diffusion. The substrate 202 may further include other functional features such as a resistor, a capacitor, diode, transistors (e.g., field effect transistors (FETs)), as well as source/drain contacts and gate contacts that extend to and electrically couple to source/drain features and gate structures of transistors underneath. A conductive feature 203 is disposed in a top portion of the substrate 202. In various embodiments, the conductive feature 203 may be one of the gate electrodes 74 or one of the source/drain contacts MD as illustrated in FIG. 1.

The workpiece 200 also includes an inter-level dielectric (ILD) layer 204 deposited above the substrate 202. In some embodiments, the ILD layer 204 may comprise dielectric material such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The dielectric material may be formed by plasma-enhanced chemical vapor deposition (PECVD), flowable chemical vapor deposition (FCVD), or other suitable methods. In some embodiments, the dielectric material is formed of a low-k (e.g., a dielectric constant value around 3.9) dielectric material or an extreme low-k (e.g., a dielectric constant value around 2.5) dielectric material, such as carbon-containing dielectric materials, and may further contain nitrogen, hydrogen, oxygen, and combinations thereof. If an extreme low-k dielectric material is used, a curing process may be followed after depositing the extreme low-k dielectric material to increase its porosity, lower the k value, and improve the mechanical strengths. The ILD layer 204 includes vias that extend through the ILD layer 204 and provide electrical coupling to the conductive features in the substrate 202. In the present embodiment, a via 205 is illustrated. The via 205 extends to and electrically couple to the conductive feature 203 underneath. In various embodiments, the via 205 may be one of the gate vias VG or one or the source/drain contact vias VD as illustrated in FIG. 1.

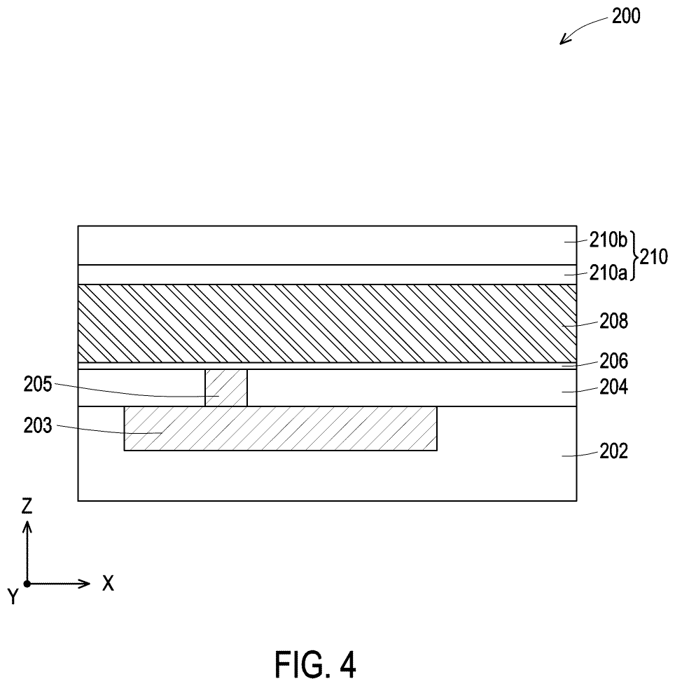

Referring to FIGS. 2 and 4, method 100 includes a block 104 where a glue layer 206, a metal layer 208, and a hard mask 210 are formed over the ILD layer 204. The glue layer 206 functionally provides adhesion between the ILD layer 204 and the subsequently deposited metal layer 208. The glue layer 206 also functions as an etch stop layer and provides end point control during subsequent etching processes. Material compositions of the glue layer 206 are selected such that an etch selectivity exists between the glue layer and the metal layer to form thereon, such that an etching process etching through the metal layer stops at the glue layer 206 without causing etching damages to the underlaying layer(s). The glue layer 206 may comprise tantalum nitride (TaN), titanium nitride (TiN), tungsten nitride (WN), or other suitable metal nitride. The glue layer 206 may be deposited using atomic layer deposition (ALD), physical vapor deposition (PVD), chemical vapor deposition (CVD), plasma enhanced CVD (PECVD), or other suitable methods. In some embodiments, the glue layer 206 has a thickness ranging from about 2 Å to about 100 Å.

The metal layer 208 is deposited over the glue layer 206. As will be discussed in further details, the metal layer 208 is to pattern into metal lines, one of which electrically couples to the via 205 and the conductive feature 203 underneath.

A common process for forming metal lines or vias in an inter-metal dielectric (IMD) layer of an interconnect structure is known as “damascene” process. Generally, a damascene process involves forming trench-like openings in an IMD layer. A trench-like opening is typically formed using conventional lithographic and etching techniques. After the trench-like opening is formed, a diffusion barrier layer and an adhesion layer are deposited within the trench-like opening. An electro-chemical plating process is then used to fill the trench-like opening with metal or metal alloys to form a metal line and possibly a via underneath the metal line as well. Excess metal material on the surface of the IMD layer is then removed by a CMP process.

With increasing packing density in microelectronic devices, copper (Cu) has been used as an interconnecting metal among other available metal materials due to its superior electrical conductivity (5.96×10⁷ S/m) and excellent resistance against electro migration. The damascene process with copper, which involves copper electroplating followed by a CMP of the copper, has been commonly adopted for patterning copper. At the meantime, as semiconductor device sizes continue to shrink, the damascene process with copper also sees a number of potential problems that may affect the quality of the metallization layers. For example, when a metal line critical dimension (CD) is below 20 nanometer (nm), a trench-like opening may become too narrow and accordingly high aspect ratio, and the stack of diffusion barrier layer and adhesion layer will occupy substantial portions of the openings, leaving less room for the more conductive copper. The remaining smaller amount of copper has higher resistance and thus degrade semiconductor device performance. This problem is particularly acute in high aspect ratio (e.g., >3) trench-like openings of a small width. Moreover, the trench-like openings may not be properly filled by a damascene process, such that the top portion of the openings may be blocked, which may create a void underneath and deteriorate device performance. Besides, narrower copper lines may have a shorter lifetime before consequent higher current density destroys them by electro migration.

As a comparison, noble metals have become technologically important as conductive features in integrated circuits. The term “noble metals” as used herein indicates metals selected from ruthenium (Ru), iridium (Ir), rhodium (Rh), platinum (Pt), palladium (Pd), osmium (Os), silver (Ag), and gold (Au). All other metals are herein categorized as non-noble metals. Unlike some non-noble metals, such as copper, which is not suitable for direct patterning, noble metals can be patterned to form metal lines with a CD less than about 20 nm due to the suitability of being directly patterned in dry etching approaches (e.g., reactive ion etching (RIE) process). In some embodiments, the metal layer 208 includes a noble metal, an alloy of two or more noble metals, or an alloy of noble metal(s) mixed with non-noble metal(s), such as copper (Cu), cobalt (Co), molybdenum (Mo), chromium (Cr), tungsten (W), manganese (Mn), and aluminum (Al). In some embodiments, the metal layer 208 includes a noble metal selected from the group of Ru, Ir, Rh, and Pt, such as Ru in a specific example. In another embodiment, the metal layer 208 includes alloy of noble metals with noble or non-noble metals, such as PtIr, PdPt, or PdNi. In yet another embodiment, the metal used to form the metal layer 208 is not limited to noble metals, as long as the metal is suitable for direct patterning, such as Co, Mo, and W. The metal layer 208 may be deposited by ALD, CVD, PVD, electroplating, or other suitable methods. The metal layer 208 may have a thickness ranging from about 50 Å to about 500 Å, in accordance with some embodiments.

The hard mask 210 is deposited on the metal layer 208 using ALD, CVD, PVD, or other suitable methods. In the illustrated embodiment, the hard mask 210 is a dual-layer structure and includes a first layer 210a and a second layer 210b formed on the first layer 210a. The first layer 210a and the second layer 210b have different compositions and may be formed of aluminum oxide, silicon oxide, silicon nitride, silicon carbonitride, silicon oxycarbide, silicon oxynitride, silicon oxycarbonitride, other suitable materials, or combinations thereof.

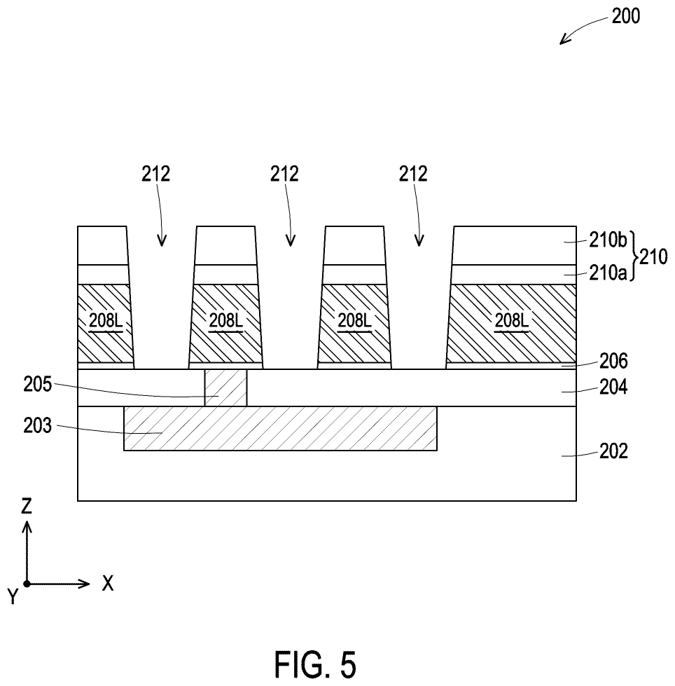

Referring to FIGS. 2 and 5, method 100 includes a block 106 where the hard mask 210 is patterned in a lithography process and an etching process, and subsequently the metal layer 208 is patterned to form metal lines in a metal etching process. Referring to FIG. 5, trenches 212 are formed after the metal layer 208 is patterned.

The hard mask 210 is patterned using suitable processes including double-patterning processes, multi-patterning processes, photolithography, self-aligned processes, and mandrel-spacer processes to define a pattern of lines to be transferred to the underneath metal layer 208. In the illustrated embodiment, a photoresist layer (not shown) is formed on the hard mask 210 using a spin-coating process and soft baking process. Then, the photoresist layer is exposed to a radiation. The radiation may be an extreme ultravoilet (EUV) radiation using a wavelength of 13.6 nm, an ultraviolet radiation using a wavelength of 436 nm, 405 nm, or 365 nm, or a DUV radiation using a wavelength of 248 nm, 193 nm, or 157 nm, or other available radiation for lithography, such as e-beam. Subsequently, the exposed photoresist layer is developed using post-exposure baking (PEB), developing, and hard baking thereby forming a patterned photoresist layer over the hard mask 210. The hard mask 210 is etched through the openings defined in the patterned photoresist layer, forming a patterned hard mask 210. The patterned photoresist layer is removed thereafter using a suitable process, such as wet stripping or plasma ashing.

The metal layer 208 is subsequently etched in a metal etching process, using the patterned hard mask 210 as an etching mask. In the illustrated embodiment, the metal etching process is a dry etching process, such as a plasma etching process. In furtherance of the embodiment, the metal etching process includes an RIE process. The RIE process may include process parameters such as reactor operating pressure ranging from about 10 mTorr to about 300 mTorr, an RF power less than 2700 W (e.g., ranging from about 900 W to about 1600 W), a bias voltage less than about 4500 W, a temperature ranging from about 10° C. to about 80° C., and an RIE etching period ranging from about 200 seconds to about 500 seconds. The RIE source gas may include an ion composition, such as argon (Ar), a fluorine-containing gas (e.g., CF₄, SF₆, CH₂F₂, CHF₃, C₄F₈, C₂F₆), or a combination thereof. The RIE source gas may further include certain chemical etchants, such as a chlorine-containing gas (e.g., Cl₂, CHCl₃, CCl₄) for chemical etching. In some embodiments, the chemical etchant comprises boron (B) (e.g., B₂F₄, BCl₃, B₄Cl₄, BBr₃). In a specific embodiment, the chemical etchant comprises a combination of boron and chlorine. In some embodiments, the total etchant flow rate is less than 1800 sccm, such as about 1200 sccm. The chemical etchant may have a flow rate about 30% to about 50% of the total etchant flow rate, such as about 40%. The resulting metal lines after the patterning of the metal layer 208 may have a critical dimension (CD) within sub-20 nm range. As discussed above, the selection of metal compositions (e.g., noble metal) for the metal layer 208 safeguards bulk metal composition with low resistivity for narrow metal lines. For the sake of simplicity, the metal lines patterned from the metal layer 208 are denoted as the metal lines 208L after operations at block 106. Trenches (or openings) 212 are sandwiched between adjacent metal lines 208L, exposing the top surface of the glue layer 206. The glue layer 206 protects the ILD layer 204 from the RIE process as an etch stop layer. Subsequently, the exposed portions of the glue layer 206 are etched in another etching process, such as a wet etching, a dry etching, or a combination thereof. The trenches 212 extends downwardly to the top surface of the ILD layer 204. The etching of the hard mask 210, the metal layer 208, and the glue layer 206 may be in-situ.

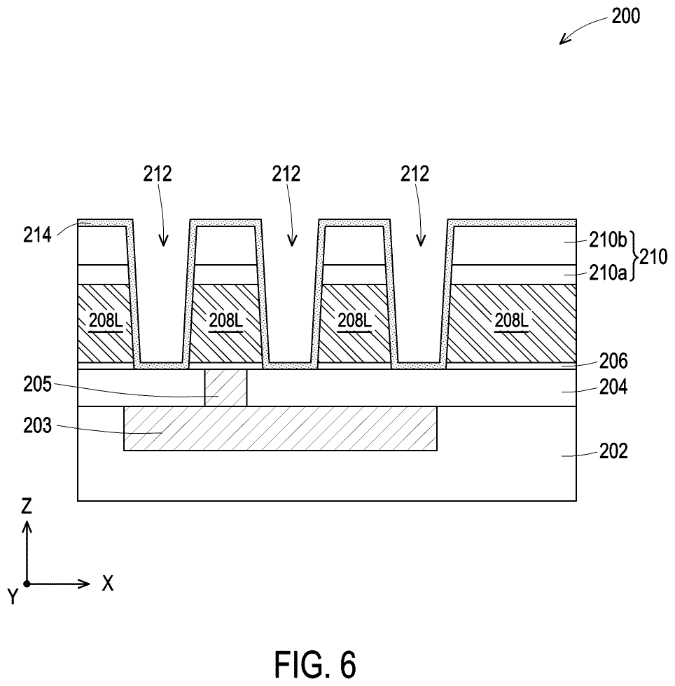

Referring to FIGS. 2 and 6, method 100 includes a block 108 where a dielectric capping layer 214 is formed over the workpiece 200. In an embodiment, the dielectric capping layer 214 is conformally deposited over the workpiece 200, including in the trenches 212, using ALD, CVD, plasma enhanced CVD (PECVD), plasma enhanced ALD (PEALD), or other suitable methods. The term “conformally” may be used herein for case of description of a layer having substantially uniform thickness over various regions. A deposition thickness of the dielectric capping layer 214 may be between about 20 Å and about 50 Å. In an embodiment, the dielectric capping layer 214 is formed of a high-kappa material. The term “high-kappa material” refers to a material with a thermal conductivity of not less than 10 W/m·K (Watts per meter-Kelvin). A high-kappa material is particularly effective at conducting heat, and is also referred to as a thermal conductive material. This means the dielectric capping layer 214 made of a high-kappa material allows heat to pass through it rapidly and efficiently. By way of example and not limitation, the dielectric capping layer 214 may include a high-kappa material, such as aluminum nitride (AlN), hexagonal boron nitride (h-BN), graphene oxide, diamond, diamond-like carbon, silicon carbide (SiC), silicon carbon nitride (SiCN), transition metal dichalcogenides (TMDs) (e.g., MoS₂, MoSe₂, WS₂ or WSe₂), or any other suitable high-kappa material. For aluminum nitride, it exhibits a high thermal conductivity of about 370 W/m·K. For TMDs, it generally exhibits a thermal conductivity above 10 W/m·K. For h-BN, it is in a layered structure in a crystalline form similar to graphite and exhibits an in-plane thermal conductivity above 390 W/m·K at room temperature. As a comparison, amorphous BN (a-BN) is in a non-crystalline amorphous form and only exhibits an in-plane thermal conductivity around 3 W/m·K, which is not considered as a high-kappa material in the context of the present disclosure.

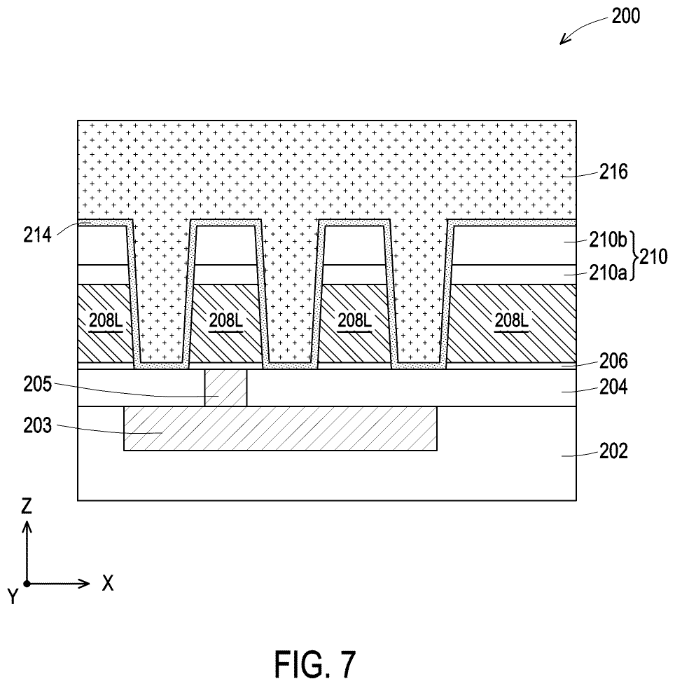

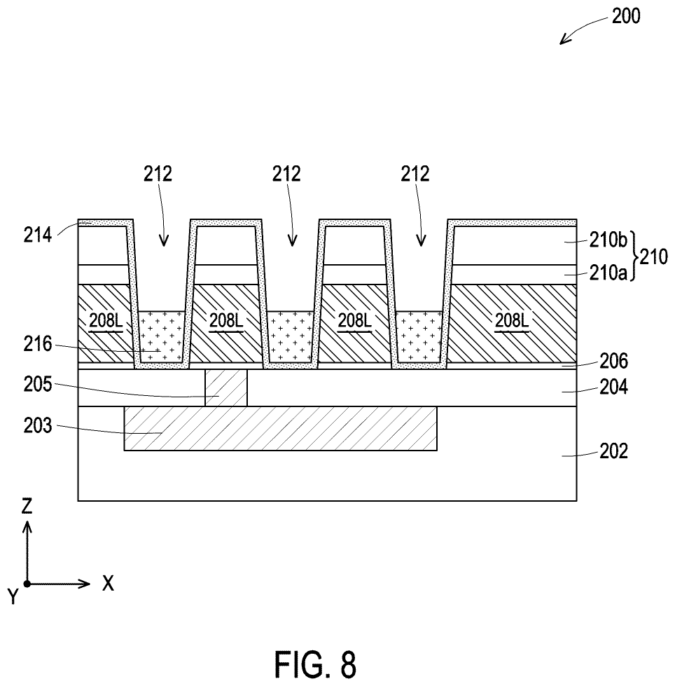

Referring to FIGS. 2 and 7-8, method 100 includes a block 110 where a sacrificial layer 216 is formed over the dielectric capping layer 214 to partially fill the trenches 212. In an example process, an organic layer (such as a polymer layer) that includes C, O, N, and H is deposited over the workpiece 200, as shown in FIG. 7. The organic layer may be deposited by using CVD, PECVD, flowable CVD (FCVD), ALD, PEALD, or spin-on coating. The deposited organic layer may be heated to increase its flowability to have a smoother top surface. A curing process may be then performed to cure the organic layer. In some instances, the curing process may include a bake process, an anneal process, a drying process, or an ultraviolet (UV) radiation process. The cured organic layer is then planarized and selectively etched back, thereby forming the sacrificial layer 216 in the lower portion of the trenches 212, as shown in FIG. 8. The sacrificial layer 216 may have a thickness ranging from about 10 Å to about 100 Å, in accordance with some embodiments. As to be discussed in further details, the etch back of the organic layer is used to define a height of air gaps between the metal lines 208L by removing the sacrificial layer 216 in a subsequent step. While the sacrificial layer 216 will be removed in a subsequent step, it is selected such that it can withstand the planarization process and the deposition of a sustaining layer (to be described below) without becoming structurally compromised. For those reasons, the sacrificial layer 216 needs to be easy to remove and yet to remain stable at about the deposition temperature of the sustaining layer. Based on these criteria, the sacrificial layer 216 may include polyvinyl alcohol (PVA), polyacrylate, polydimethylsiloxane (PDMS), polycarbonate (PC), or other suitable polymers.

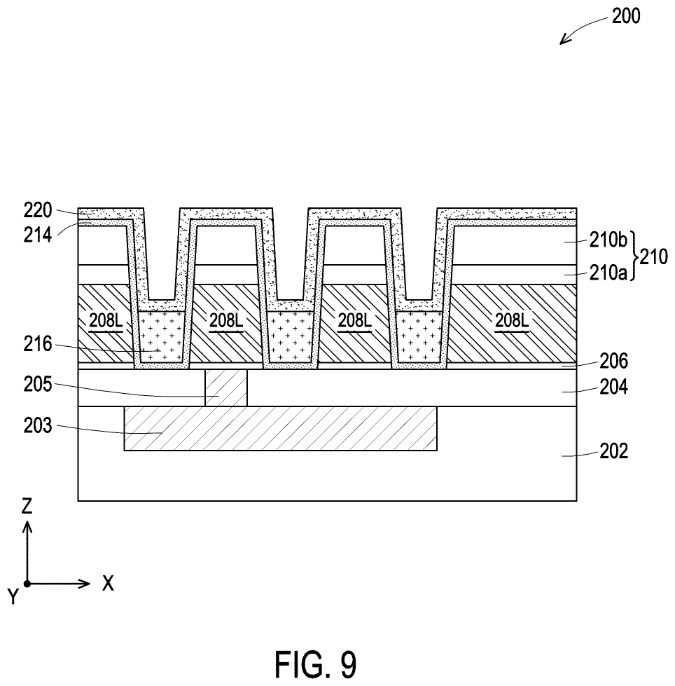

Referring to FIGS. 2 and 9, method 100 includes a block 112 where a sustaining layer 220 is formed over the workpiece 200. In some embodiments, a low-k dielectric material is conformally deposited over the workpiece 200, including on the sacrificial layer 216 and the dielectric capping layer 214, to form a sustaining layer 220 which has a loose structure and covers the sacrificial layer 216. In some embodiments, the sustaining layer 220 has a porous structure. The deposition for forming the sustaining layer 220 may be implemented by PVD, CVD, ALD, PECVD, PEALD, or other suitable processes. In some embodiments, the sustaining layer 220 includes silicon oxide, silicon carbon oxide, silicon oxynitride, silicon carbon nitride, silicon carbon oxynitride, or other suitable dielectric material. The sustaining layer 220 may have a thickness ranging from about 2 Å to about 100 Å, in accordance with some embodiments.

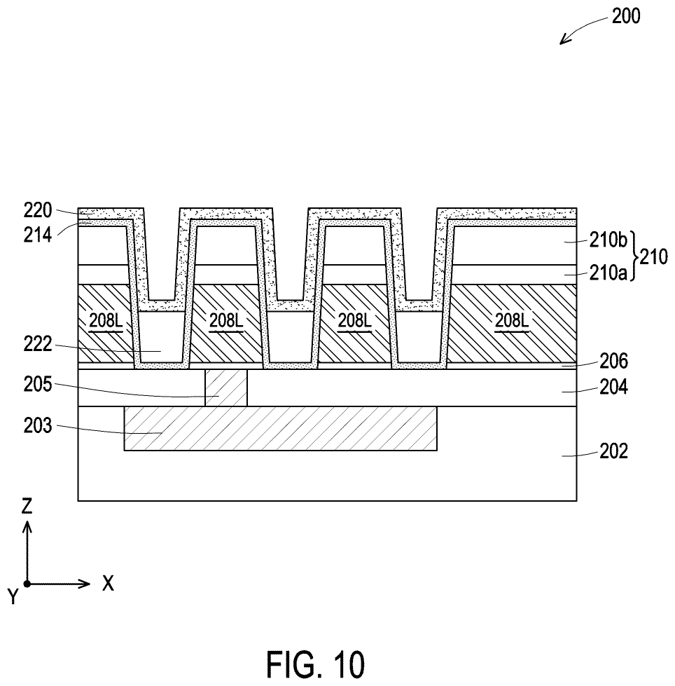

Referring to FIGS. 2 and 10, method 100 includes a block 114 where the sacrificial layer 216 is selectively removed to form air gaps 222 between the metal lines 208L and under the sustaining layer 220. In some embodiments, a thermal treatment (e.g., an anneal process, a baking process) and/or an ultraviolet process may be performed to decompose the sacrificial layer 216 into volatile compound that can be diffused through the porous structure of the sustaining layer 220. The removal of the sacrificial layer 216 forms air gaps 222. As depicted by FIG. 10, each of the air gaps 222 is confined by the dielectric capping layer 214 and the sustaining layer 220. Because air has a dielectric constant close to 1, the air gaps 222 lower the effective dielectric constant of the dielectric structures among the metal lines 208L.

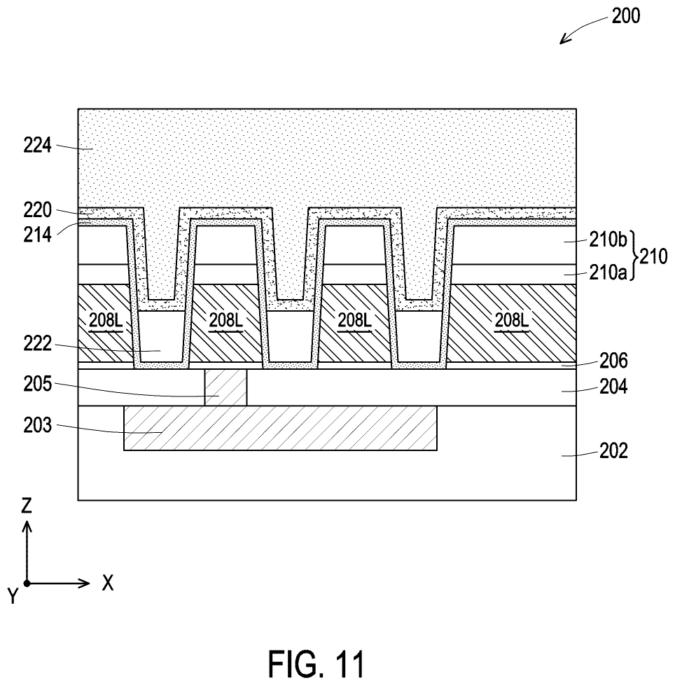

Referring to FIGS. 2 and 11, method 100 includes a block 116 where a high thermal conductivity (high-kappa) material layer 224 is formed over the sustaining layer 220 using ALD, CVD, plasma enhanced CVD (PECVD), or microwave PECVD. In some embodiments, the high-kappa material layer 224 may include diamond or diamond-like carbon. In some other embodiments, the high-kappa material layer 224 includes aluminum nitride (AlN), hexagonal boron nitride (h-BN), graphene oxide, silicon carbide (SiC), silicon carbon nitride (SiCN). In furtherance of some embodiments, the high-kappa material is a low-k (e.g., a dielectric constant value around 3.9) dielectric material. The high-kappa material layer 224 may have a thickness ranging from about 10 Å to about 700 Å, in accordance with some embodiments. The high-kappa materials in the dielectric capping layer 214 and the high-kappa material layer 224 may be the same or different. For example, the high-kappa material layer 224 may have a higher thermal conductivity than the dielectric capping layer 214. The sustaining layer 220 separates the high-kappa material layer 224 from contacting the dielectric capping layer 214.

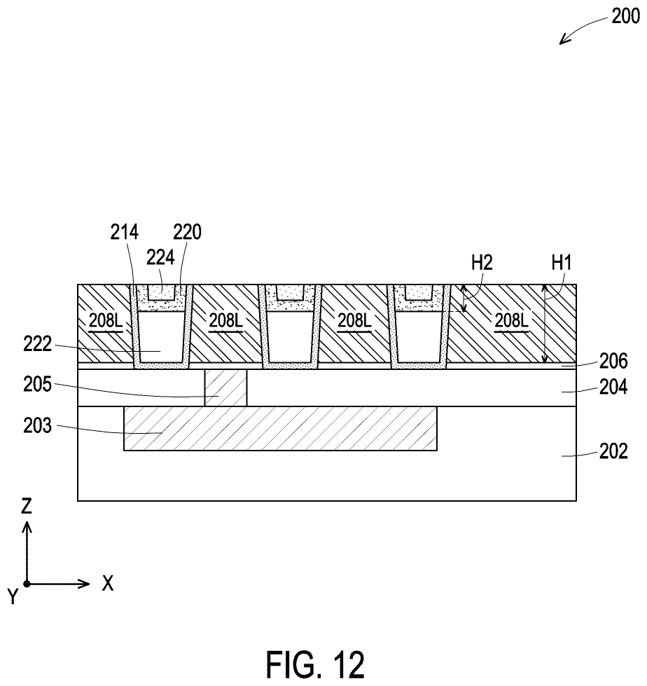

Referring to FIGS. 2 and 12, method 100 includes a block 118 where the workpiece 200 is planarized to expose the metal lines 208L. After forming the high-kappa material layer 224, a planarization process is performed to the workpiece 200. In an embodiment, the planarization process stops after exposing the top surface of the metal lines 208L. Upon completion of the planarization process, a topmost surface of the dielectric capping layer 214, a topmost surface of the sustaining layer 220, and a top surface of the high-kappa material layer 224 are coplanar. The sustaining layer 220 extends along bottom and sidewall surfaces of the high-kappa material layer 224 and is in contact with the dielectric capping layer 214. The dielectric capping layer 214, the sustaining layer 220, the high-kappa material layer 224, and the air gap 222 trapped between the dielectric capping layer 214 and the sustaining layer 220 collectively define the dielectric structure disposed between two adjacent metal lines 208L. Since air has a dielectric constant close to 1, the air gaps 222 lower the effective dielectric constant of the dielectric structures between the metal lines 208L. In other words, the air gaps 222 between metal lines help keep a low parasitic capacitance between the metal lines 208L. Meanwhile, the high-kappa nature due to the applying of high-kappa materials in the combo of the dielectric capping layer 214, the sustaining layer 220, and the high-kappa material layer 224 allows heat to propagate horizontally among the metal lines 208L, such that heat is less likely to be confined in this metal line layer. In some embodiments, a height H2 measured from the top surface of the high-kappa material layer 224 to the bottom surface of the sustaining layer 220 is about 20% to about 50% of a height H1 of the metal lines 208L. The range from about 20% to about 50% is not trivial or arbitrary. If the ratio of H2/H1 is less than about 20%, the thermal dissipation capability may be compromised due to the rather thin high-kappa material layer 224; if the ratio of H2/H1 is larger than about 50%, the parasitic capacitance may become too large and thus reduce circuit speed due to the rather small volume of the air gaps 222.

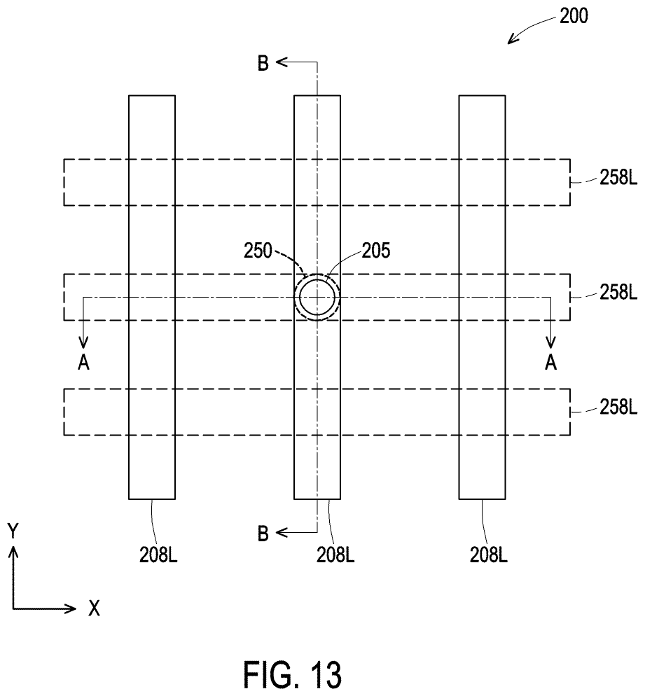

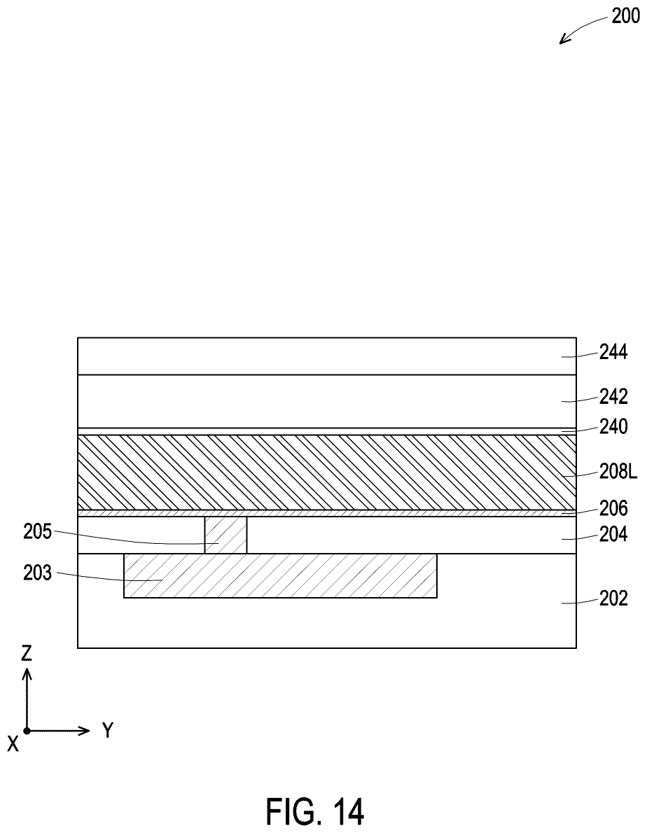

FIG. 13 depicts a fragmentary top view of the workpiece shown in FIG. 12 at the conclusion of operations at block 118. More specifically, FIGS. 3-12 are along the A-A cut in FIG. 13. FIG. 13 illustrates the metal lines 208L each extending lengthwise in the Y direction and arranged in the X direction. The metal lines 258L to be formed subsequently in one metal line layer immediately above the metal lines 208L are depicted in dashed rectangular boxes. The vias 250 to be formed in electrically connecting the metal lines 208L to the metal lines 258L are depicted in dashed circles. The metal lines 258L each extends lengthwise in the X direction and arranged in the Y direction. In an embodiment, the metal lines 208L represents the M0 metal lines and the via 205 represents one of the V0 vias, thus the to-be-formed metal lines 258L represents the M1 metal lines and the to-be-formed vias 250 represents the V1 vias. In another embodiment, the metal lines 208L may represent the M1 metal lines and the via 205 represents one of the V1 vias, thus the to-be-formed metal lines 258L represents the M2 metal lines and the to-be-formed vias 250 represents the V2 vias. FIGS. 14-26 depict the formation of the metal lines 258L and one of the vias 250, which are along the B-B cut in FIG. 13.

Referring to FIGS. 2 and 14, method 100 includes a block 120 where a first etch stop layer (ESL) 240, a low dielectric constant (or low-k) dielectric layer 242, and a hard mask 244 are formed over the metal lines 208L, as well as on the dielectric capping layer 214, the sustaining layer 220, and the high-kappa material layer 224 (FIG. 12). In some embodiments, the first ESL 240 may include aluminum oxide, aluminum nitride, silicon nitride, silicon oxycarbide, silicon carbonitride, or a combination thereof and may be deposited using atomic layer deposition (ALD), physical vapor deposition (PVD), chemical vapor deposition (CVD), or plasma enhanced CVD (PECVD). After forming the first ESL 240, the low-k dielectric layer 242 is formed. The low-k dielectric layer 242 has a dielectric constant smaller than that of silicon oxide, which is about 3.9. For example, the low-k dielectric layer 242 may include a porous organosilicate thin film (e.g., SiCOH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. The hard mask 244 is deposited on the low-k dielectric layer 242 using ALD, CVD, PVD, or other suitable methods. In the illustrated embodiment, the hard mask 244 is a single-layer structure of a dual-layer structure. The hard mask 244 may be formed of aluminum oxide, silicon oxide, silicon nitride, silicon carbonitride, silicon oxycarbide, silicon oxynitride, silicon oxycarbonitride, other suitable materials, or combinations thereof.

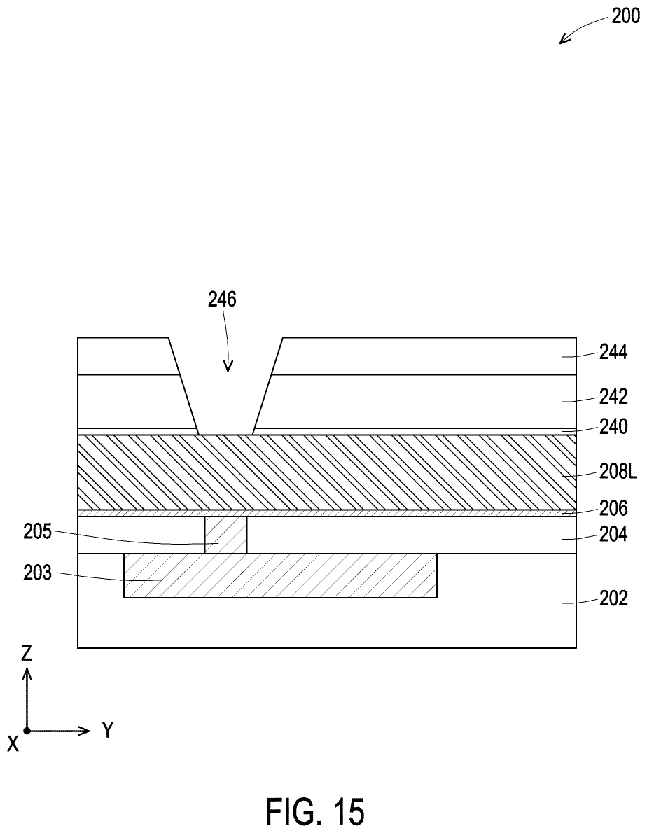

Referring to FIGS. 2 and 15, method 100 includes a block 122 where the hard mask 244, the low-k dielectric layer 242, and the first ESL 240 are patterned to form a via opening 246. The patterning of the hard mask 244, the low-k dielectric layer 242, and the first ESL 240 may include photolithography processes and etching processes, such as deposition of a photoresist layer, photolithographic patterning of the photoresist layer, etching of the hard mask 244, and subsequently the low-k dielectric layer 242 and the first ESL 240 using the patterned photoresist layer and patterned hard mask 244 as an etch mask, and selective removal of the photoresist layer. The photoresist layer may include hydrocarbons and may be deposited using spin-on coating. The etching of the low-k dielectric layer 242 and the first ESL 240 may include dry etching, wet etching, reactive ion etching (RIE), and/or other suitable processes. After forming the via opening 246, the photoresist layer may be removed by ashing or selective etching.

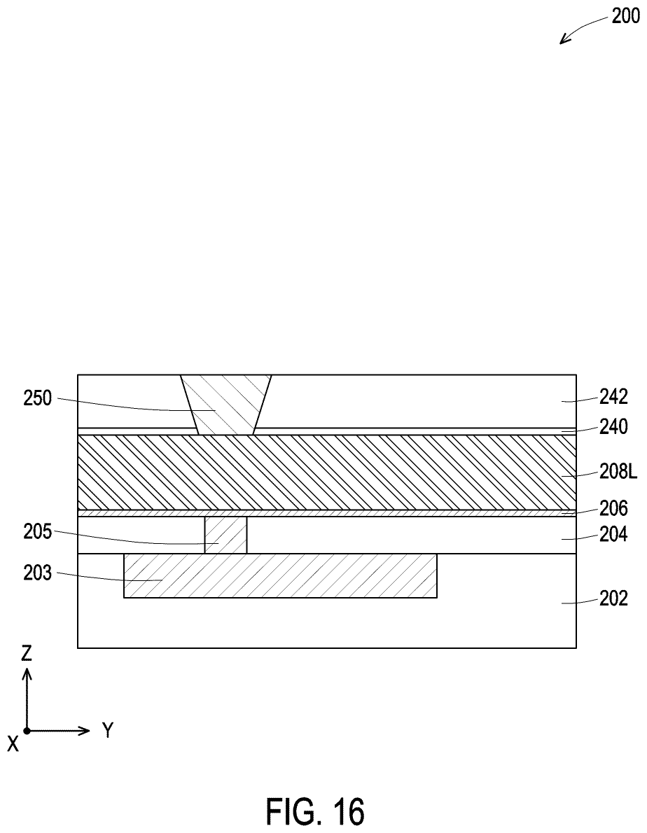

Referring to FIGS. 2 and 16, method 100 includes a block 124 where a via 250 is formed in the via opening 246. The via 250 extend through the low-k dielectric layer 242 and the first ESL 240 to couple to the metal line 208L. In some embodiments, a metal material layer is first deposited over the workpiece 200, including in the via opening 246. In some embodiments, the metal material layer (and the via 250 formed therefrom) includes ruthenium (Ru), tungsten (W), molybdenum (Mo), combinations thereof, or other suitable conductive materials that are less prone to diffusion issues. In some embodiments, the via 250 is made of a metal different from the metal lines 208L. In some alternative embodiments, the via 250 and the metal lines 208L are made of the same metal. The metal material layer may be deposited using ALD, CVD, PEALD, PECVD, electroplating, or electroless deposition. After deposition of the metal material layer, a planarization process, such as a chemical mechanical polishing (CMP) process, is performed to remove excess metal material layer and the hard mask 244 to expose the top surface of the low-k dielectric layer 242. After the planarization process, the via 250 is formed in the via opening 246. To reduce a parasitic resistance, the via 250 may be formed of metal and does not include a barrier layer. Forming a barrier-free via 250 advantageously reduces parasitic resistance (e.g., contact resistance) of the workpiece 200.

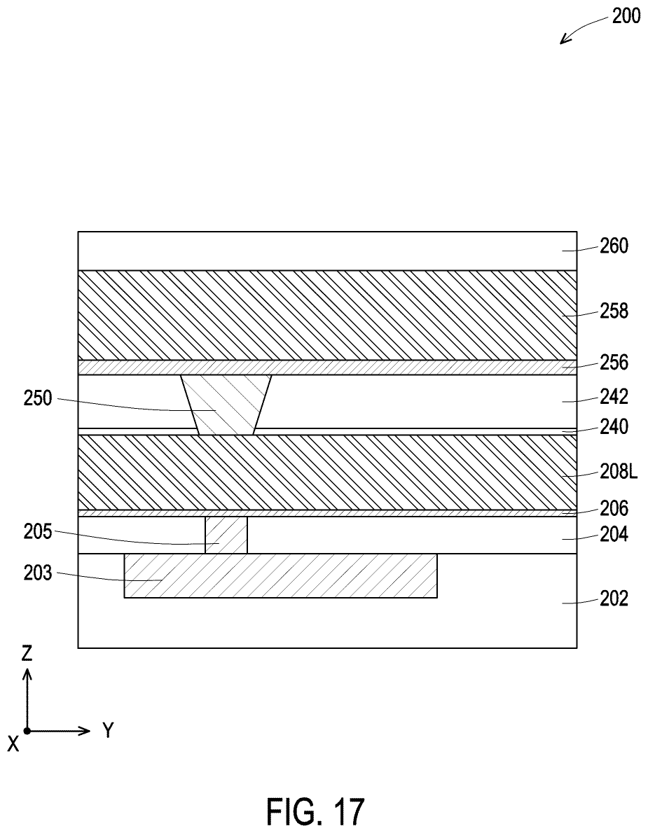

Referring to FIGS. 2 and 17, method 100 includes a block 126 where a glue layer 256, a metal layer 258, and a hard mask 260 are formed over the low-k dielectric layer 242 and the via 250. The glue layer 256 functionally provides adhesion between the low-k dielectric layer 242 and the subsequently deposited metal layer 258. The glue layer 256 also functions as an etch stop layer and provides end point control during subsequent etching processes. Material compositions of the glue layer 256 are selected such that an etch selectivity exists between the glue layer and the metal layer to form thereon, such that an etching process etching through the metal layer stops at the glue layer 256 without causing etching damages to the underlaying layer(s). The glue layer 256 may comprise tantalum nitride (TaN), titanium nitride (TiN), tungsten nitride (WN), or other suitable metal nitride. The glue layer 256 may be deposited using atomic layer deposition (ALD), physical vapor deposition (PVD), chemical vapor deposition (CVD), plasma enhanced CVD (PECVD), or other suitable methods. In some embodiments, the glue layer 256 has a thickness ranging from about 2 Å to about 100 Å.

The metal layer 258 is deposited over the glue layer 206. Similar to the metal layer 208, the metal layer 258 is formed of a metal suitable for direct patterning. In some embodiments, the metal layer 258 includes a noble metal, such as ruthenium (Ru), iridium (Ir), rhodium (Rh), platinum (Pt), palladium (Pd), osmium (Os), silver (Ag), and gold (Au). In some embodiments, the metal layer 258 includes an alloy of two or more noble metals, or an alloy of noble metal(s) mixed with non-noble metal(s), such as copper (Cu), cobalt (Co), molybdenum (Mo), chromium (Cr), tungsten (W), manganese (Mn), and aluminum (Al). In some embodiments, the metal layer 258 includes a noble metal selected from the group of Ru, Ir, Rh, and Pt, such as Ru in a specific example. In another embodiment, the metal layer 258 includes alloy of noble metals with noble or non-noble metals, such as PtIr, PdPt, or PdNi. In yet another embodiment, the metal used to form the metal layer 258 is not limited to noble metals, as long as the metal is suitable for direct patterning, such as Co, Mo, and W. In some embodiments, the metal layer 208 and the metal layer 258 include different metals, such as two different noble metals. Alternatively, the metal layer 208 and the metal layer 258 may include the same metal, such as the same noble metal (e.g., Ru). The metal layer 258 may be deposited by ALD, CVD, PVD, electroplating, or other suitable methods. The metal layer 208 may have a thickness ranging from about 50 Å to about 500 Å, in accordance with some embodiments.

The hard mask 260 is deposited on the metal layer 258 using ALD, CVD, PVD, or other suitable methods. In the illustrated embodiment, the hard mask 260 is a single-layer structure of a dual-layer structure. The hard mask 260 may be formed of aluminum oxide, silicon oxide, silicon nitride, silicon carbonitride, silicon oxycarbide, silicon oxynitride, silicon oxycarbonitride, other suitable materials, or combinations thereof.

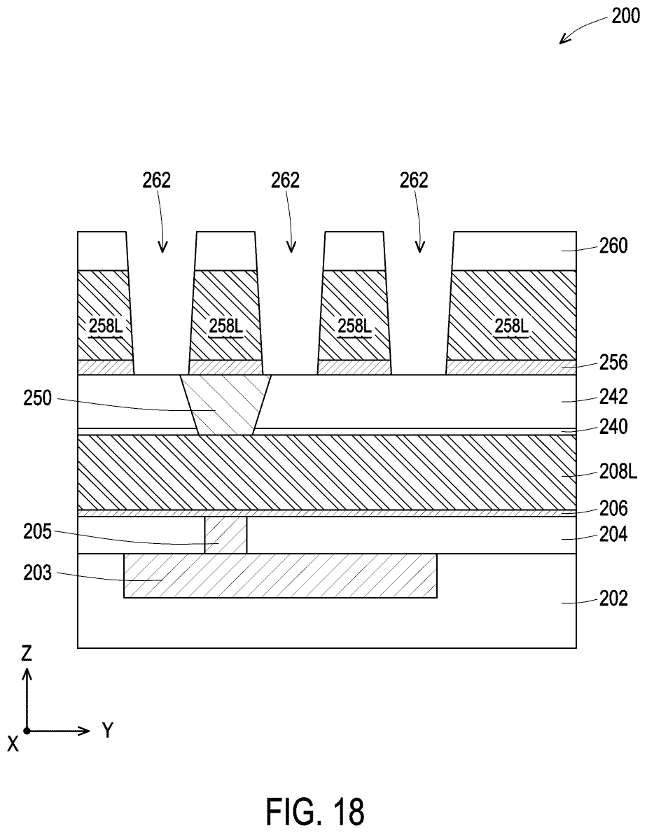

Referring to FIGS. 2 and 18, method 100 includes a block 128 where the hard mask 260 is patterned in a lithography process and an etching process, and subsequently the metal layer 258 is patterned to form metal lines in a metal etching process. Trenches 262 are formed after the metal layer 208 is patterned.

The hard mask 260 is patterned using suitable processes including double-patterning processes, multi-patterning processes, photolithography, self-aligned processes, and mandrel-spacer processes to define a pattern of lines to be transferred to the underneath metal layer 258. In the illustrated embodiment, a photoresist layer (not shown) is formed on the hard mask 260 using a spin-coating process and soft baking process. Then, the photoresist layer is exposed to a radiation. The radiation may be an extreme ultravoilet (EUV) radiation using a wavelength of 13.6 nm, an ultraviolet radiation using a wavelength of 436 nm, 405 nm, or 365 nm, or a DUV radiation using a wavelength of 248 nm, 193 nm, or 157 nm, or other available radiation for lithography, such as e-beam. Subsequently, the exposed photoresist layer is developed using post-exposure baking (PEB), developing, and hard baking thereby forming a patterned photoresist layer over the hard mask 260. The hard mask 260 is etched through the openings defined in the patterned photoresist layer, forming a patterned hard mask 260. The patterned photoresist layer is removed thereafter using a suitable process, such as wet stripping or plasma ashing.

The metal layer 258 is subsequently etched in a metal etching process, using the patterned hard mask 260 as an etching mask. In the illustrated embodiment, the metal etching process is a dry etching process, such as a plasma etching process. In furtherance of the embodiment, the metal etching process includes an RIE process. The RIE process may be similar to the one applied in etching the metal layer 208. For the sake of simplicity, the metal lines patterned from the metal layer 258 are denoted as the metal lines 258L after operations at block 128. Trenches (or openings) 262 are sandwiched between adjacent metal lines 258L, exposing the top surface of the glue layer 256. The glue layer 206 protects the low-k dielectric layer 242 from the RIE process as an etch stop layer. Subsequently, the exposed portions of the glue layer 206 are etched in another etching process, such as a wet etching, a dry etching, or a combination thereof. The trenches 262 extend downwardly to the top surface of the low-k dielectric layer 242. The etching of the hard mask 260, the metal layer 258, and the glue layer 256 may be in-situ. As depicted in FIG. 18, depending on the position of the trenches 262, a top surface of the via 250 may be partially exposed in one or more of the trenches 262.

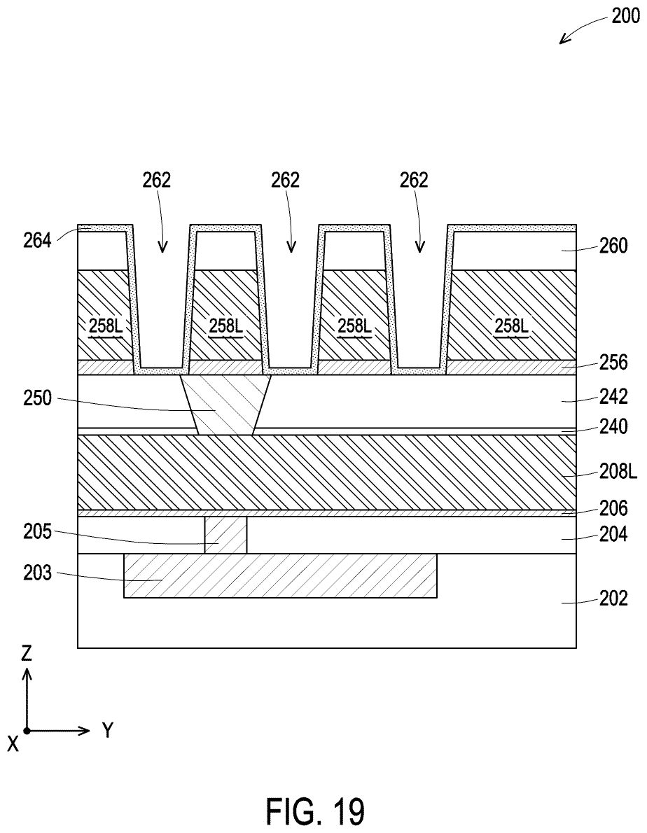

Referring to FIGS. 2 and 19, method 100 includes a block 130 where a dielectric capping layer 264 is formed over the workpiece 200. In an embodiment, the dielectric capping layer 264 is conformally deposited over the workpiece 200, including in the trenches 262, using ALD, CVD, plasma enhanced CVD (PECVD), plasma enhanced ALD (PEALD), or other suitable methods. A deposition thickness of the dielectric capping layer 214 may be between about 20 Å and about 50 Å. In an embodiment, the dielectric capping layer 214 is formed of a high-kappa material with a thermal conductivity of not less than 10 W/m·K. This means the dielectric capping layer 264 made of a high-kappa material allows heat to pass through it rapidly and efficiently. By way of example and not limitation, the dielectric capping layer 264 may include a high-kappa material, such as aluminum nitride (AlN), hexagonal boron nitride (h-BN), graphene oxide, diamond, diamond-like carbon, silicon carbide (SiC), silicon carbon nitride (SiCN), transition metal dichalcogenides (TMDs) (e.g., MoS₂, MoSe₂, WS₂ or WSe₂), or any other suitable high-kappa material. In some embodiments, the dielectric capping layer 264 and the dielectric capping layer 214 underneath may include different high-kappa materials. Alternatively, the dielectric capping layer 264 and the dielectric capping layer 214 underneath may include the same high-kappa material. In the illustrated embodiment, if a top surface of the via 250 may be partially exposed in one or more of the trenches 262, the dielectric capping layer 214 is in contact with the via 250.

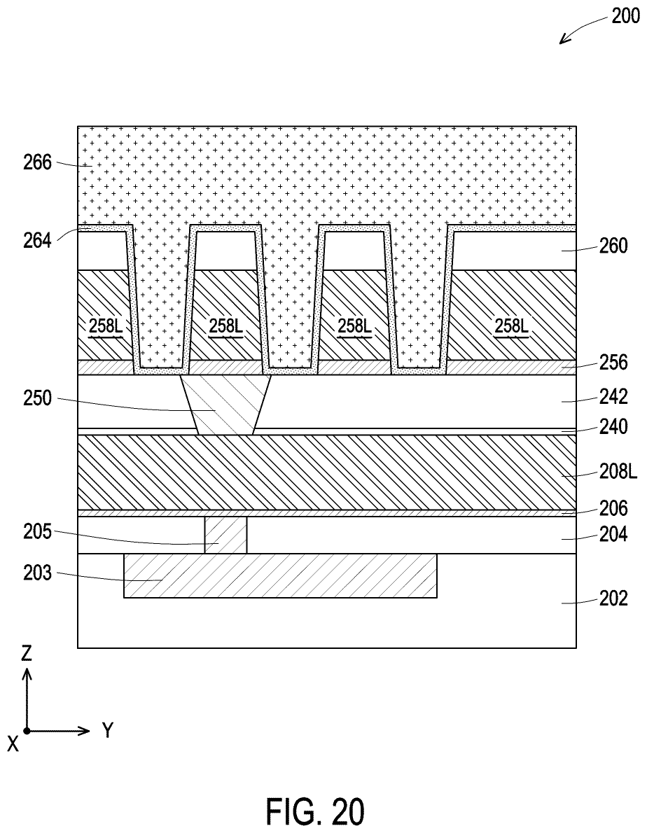

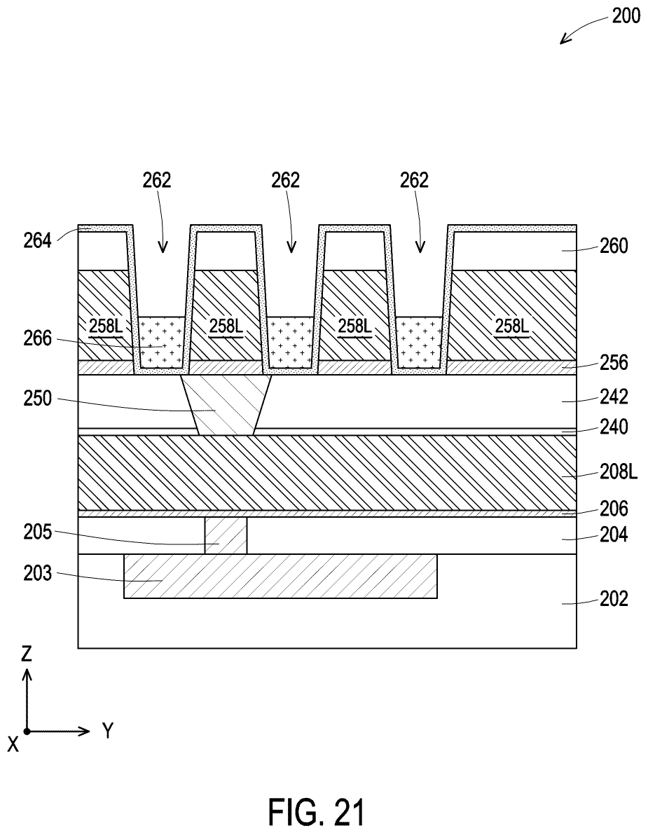

Referring to FIGS. 2 and 20-21, method 100 includes a block 132 where a sacrificial layer 266 is formed over the dielectric capping layer 264 to partially fill the trenches 262. In an example process, an organic layer (such as a polymer layer) that includes C, O, N, and H is deposited over the workpiece 200, as shown in FIG. 20. The organic layer may be deposited by using CVD, PECVD, flowable CVD (FCVD), ALD, PEALD, or spin-on coating. The deposited organic layer may be heated to increase its flowability to have a smoother top surface. A curing process may be then performed to cure the organic layer. In some instances, the curing process may include a bake process, an anneal process, a drying process, or an ultraviolet (UV) radiation process. The cured organic layer is then planarized and selectively etched back, thereby forming the sacrificial layer 266 in the lower portion of the trenches 262, as shown in FIG. 21. The sacrificial layer 266 may have a thickness ranging from about 10 Å to about 100 Å, in accordance with some embodiments. As to be discussed in further details, the etch back of the organic layer is used to define a height of air gaps between the metal lines 258L by removing the sacrificial layer 266 in a subsequent step. While the sacrificial layer 266 will be removed in a subsequent step, it is selected such that it can withstand the planarization process and the deposition of a sustaining layer (to be described below) without becoming structurally compromised. For those reasons, the sacrificial layer 266 needs to be easy to remove and yet to remain stable at about the deposition temperature of the sustaining layer. Based on these criteria, the sacrificial layer 266 may include polyvinyl alcohol (PVA), polyacrylate, polydimethylsiloxane (PDMS), polycarbonate (PC), or other suitable polymers. In some embodiments, the sacrificial layer 266 and the sacrificial layer 216 underneath may include different organic materials. Alternatively, the sacrificial layer 266 and the sacrificial layer 216 underneath may include the same organic material.

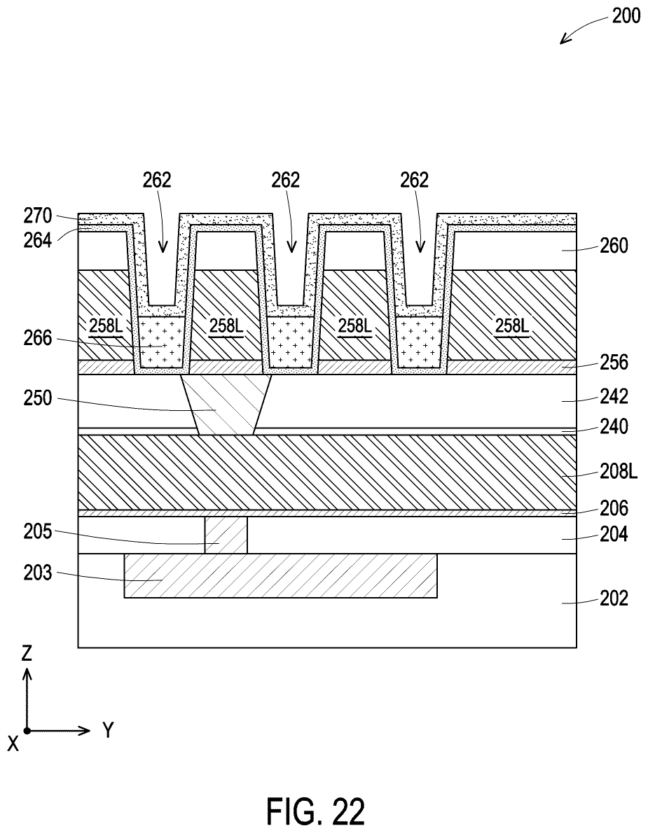

Referring to FIGS. 2 and 22, method 100 includes a block 134 where a sustaining layer 270 is formed over the workpiece 200. In some embodiments, a low-k dielectric material is conformally deposited over the workpiece 200, including on the sacrificial layer 266 and the dielectric capping layer 264, to form a sustaining layer 270 which has a loose structure and covers the sacrificial layer 266. In some embodiments, the sustaining layer 270 has a porous structure. The deposition for forming the sustaining layer 270 may be implemented by PVD, CVD, ALD, PECVD, PEALD, or other suitable processes. In some embodiments, the sustaining layer 270 includes silicon oxide, silicon carbon oxide, silicon oxynitride, silicon carbon nitride, silicon carbon oxynitride, or other suitable dielectric material. In some embodiments, the sustaining layer 270 and the sustaining layer 220 underneath may include different material compositions. Alternatively, the sustaining layer 270 and the sustaining layer 220 underneath may include the same material composition. The sustaining layer 270 may have a thickness ranging from about 2 Å to about 100 Å, in accordance with some embodiments.

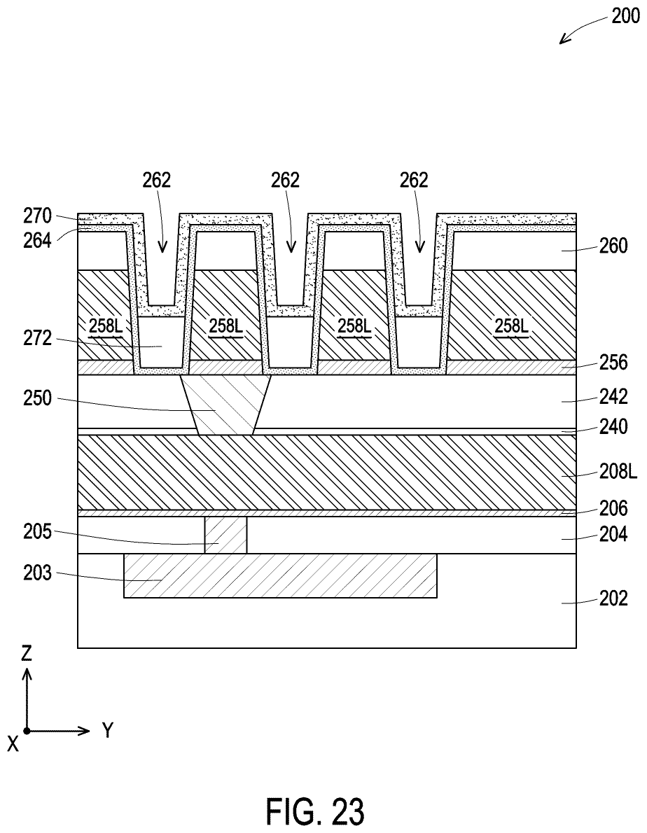

Referring to FIGS. 2 and 23, method 100 includes a block 136 where the sacrificial layer 266 is selectively removed to form air gaps 272 between the metal lines 258L and under the sustaining layer 270. In some embodiments, a thermal treatment (e.g., an anneal process, a baking process) and/or an ultraviolet process may be performed to decompose the sacrificial layer 266 into volatile compound that can be diffused through the porous structure of the sustaining layer 270. The removal of the sacrificial layer 266 forms air gaps 272. As depicted by FIG. 23, each of the air gaps 272 is confined by the dielectric capping layer 264 and the sustaining layer 270. Because air has a dielectric constant close to 1, the air gaps 272 lower the effective dielectric constant of the dielectric structures among the metal lines 258L.

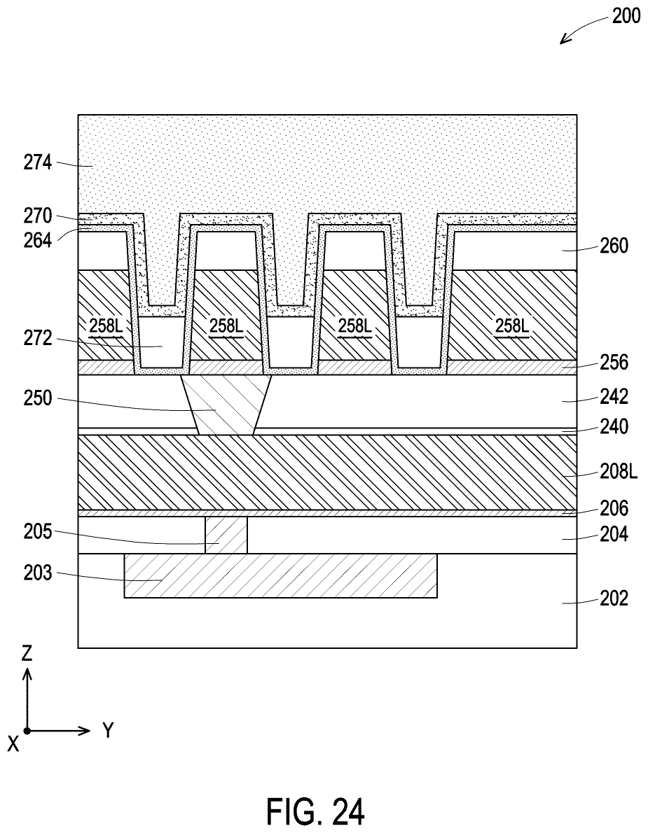

Referring to FIGS. 2 and 24, method 100 includes a block 138 where a high thermal conductivity (high-kappa) material layer 274 is formed over the sustaining layer 270 using ALD, CVD, plasma enhanced CVD (PECVD), or microwave PECVD. In some embodiments, the high-kappa material layer 274 may include diamond, diamond-like carbon. In some other embodiments, the high-kappa material layer 274 includes aluminum nitride (AlN), hexagonal boron nitride (h-BN), graphene oxide, silicon carbide (SiC), silicon carbon nitride (SiCN). In furtherance of some embodiments, the high-kappa material is a low-k (e.g., a dielectric constant value around 3.9) dielectric material. The high-kappa material layer 274 may have a thickness ranging from about 10 Å to about 700 Å, in accordance with some embodiments. The high-kappa materials in the dielectric capping layer 264 and the high-kappa material layer 274 may be the same or different. For example, the high-kappa material layer 274 may have a higher thermal conductivity than the dielectric capping layer 264. Further, in some embodiments, the high-kappa material layer 274 and the high-kappa material layer 224 underneath may include different high-kappa materials. Alternatively, the high-kappa material layer 274 and the high-kappa material layer 224 underneath may include the same high-kappa material. The sustaining layer 270 separates the high-kappa material layer 274 from contacting the dielectric capping layer 264.

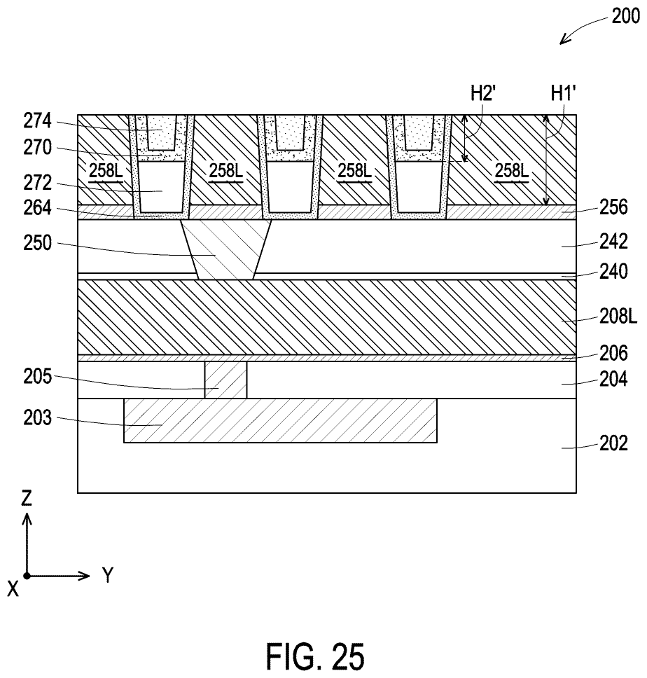

Referring to FIGS. 2 and 25, method 100 includes a block 140 where the workpiece 200 is planarized to expose the metal lines 258L. After forming the high-kappa dielectric material layer 274, a planarization process is performed to the workpiece 200. In an embodiment, the planarization process stops after exposing the top surface of the metal lines 258L. Upon completion of the planarization process, a topmost surface of the dielectric capping layer 264, a topmost surface of the sustaining layer 270, and a top surface of the high-kappa material layer 274 are coplanar. The sustaining layer 270 extends along bottom and sidewall surfaces of the high-kappa material layer 274 and is in contact with the dielectric capping layer 264. The dielectric capping layer 264, the sustaining layer 270, the high-kappa material layer 274, and the air gap 272 trapped between the dielectric capping layer 264 and the sustaining layer 270 collectively define the dielectric structure disposed between adjacent metal lines 258L. Since air has a dielectric constant close to 1, the air gaps 272 lower the effective dielectric constant of the dielectric structures between the metal lines 258L. In other words, the air gaps 272 between metal lines help keep a low parasitic capacitance between the metal lines 258L. Meanwhile, the high-kappa nature due to the applying of high-kappa materials in the combo of the dielectric capping layer 264, the sustaining layer 270, and the high-kappa material layer 274 allows heat to propagate horizontally among the metal lines 258L, such that heat is less likely to be confined in this metal line layer. In some embodiments, a height H2′ measured from the top surface of the high-kappa material layer 274 to the bottom surface of the sustaining layer 270 is about 20% to about 50% of a height H1′ of the metal lines 258L. The range from about 20% to about 50% is not trivial or arbitrary. If the ratio of H2′/H1′ is less than about 20%, the thermal dissipation capability may be compromised due to the rather thin high-kappa material layer 274; if the ratio of H2′/H1′ is larger than about 50%, the parasitic capacitance may become too large and reduce circuit speed due to the rather small volume of the air gaps 272. In some embodiments, the height H2′ may be larger than the height H2 (FIG. 12). Alternatively, the height H2′ may be the same with the height H2. In some embodiments, the height H1′ may be larger than the height H1 (FIG. 12). Alternatively, the height H1′ may be the same with the height H1.

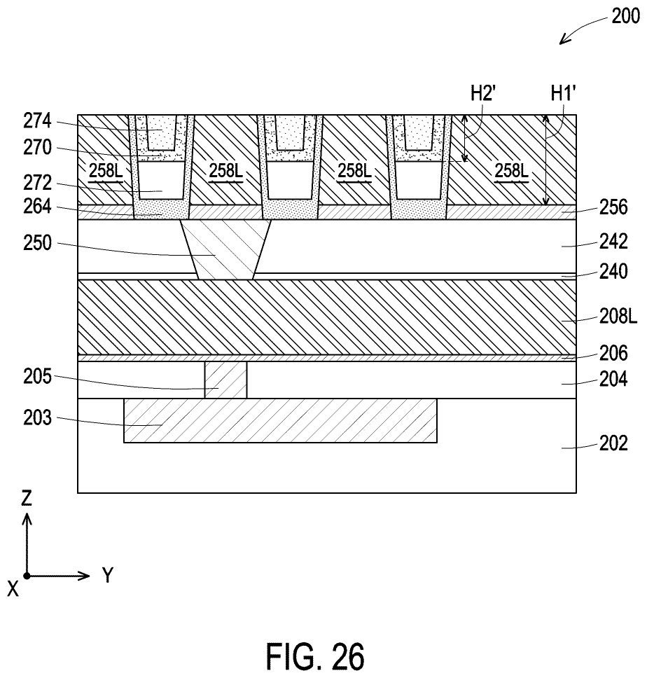

Still referring to FIG. 25, the metal line 258L in electrical coupling with the via 250 is a functional metal line for conducting signal and/or power. The two immediately adjacent metal lines 258L may be functional metal lines as well. Alternatively, the two immediately adjacent metal lines 258L may be non-functional (or dummy) metal lines, such as metal fill lines for improving metal density in the respective metal line layer and/or as grounded metal lines for shielding interference for the metal line sandwiched therebetween. Further, as depicted in FIG. 25, the thickness of the dielectric capping layer 264 is smaller than the thickness of the glue layer 256. In an alternative embodiment as depicted in FIG. 26, the thickness of the dielectric capping layer 264 may be larger than the thickness of the glue layer 256, such that a horizontal portion of the dielectric capping layer 264 bridges two adjacent metal lines 258L. The bridging of two adjacent metal lines 258L with the horizontal portion of the dielectric capping layer 264 provides an extra thermal dissipation path in the horizontal direction, such that heat can also directly travel through the horizontal portion of the dielectric capping layer 264. As depicted in FIG. 26, the horizontal portion of the dielectric capping layer 264 is thicker than vertical portions of the dielectric capping layer 264, which may be due to a selective deposition process that allows the deposition rate of a high-kappa material on the dielectric surface of the low-k dielectric layer 242 to be higher than on the metal surface of the metal lines 258L. Alternatively, the thickness of the dielectric capping layer 264 may be conformal, such that the vertical portions of the dielectric capping layer 264 are also thicker than the glue layer 256.

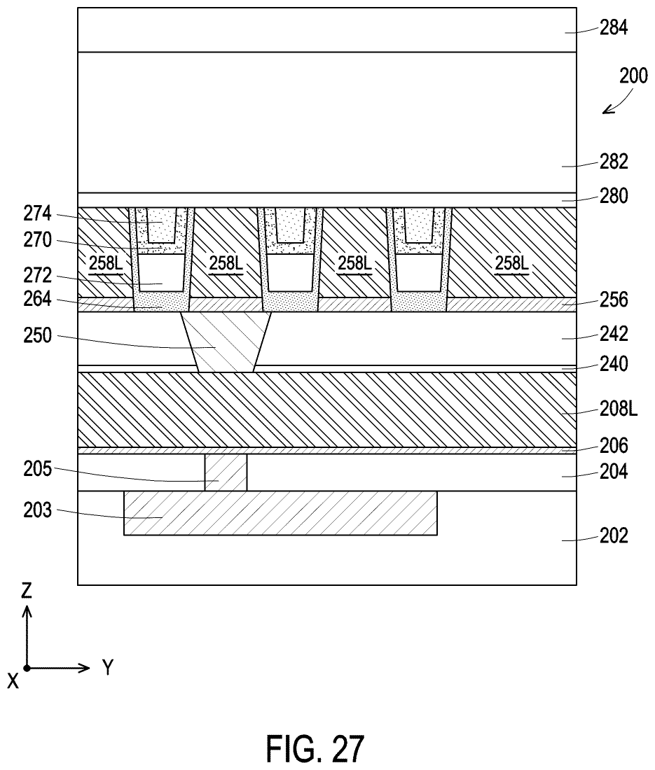

After forming the metal lines 258L, the method proceeds to block 142 to perform further processes in completing the manufacturing of the semiconductor device. For example, operations at blocks 120-140 may be repeated to form interconnect layers over the metal lines 258L. Such further processes may include forming a backside multilayer interconnect structure BMLI under the device level DL (FIG. 1). Alternatively, a damascene process other than operations at blocks 120-140 may be applied to form interconnect layers over the metal lines 258L, which is further illustrated in FIGS. 27-29.

Referring to FIG. 27, a second etch stop layer (ESL) 280, a low-k dielectric layer 282, and a hard mask 284 are formed over the metal lines 258L, as well as on the dielectric capping layer 264, the sustaining layer 270, and the high-kappa material layer 274. In some embodiments, the second ESL 280 may include aluminum oxide, aluminum nitride, silicon nitride, silicon oxycarbide, silicon carbonitride, or a combination thereof. After forming the second ESL 280, the low-k dielectric layer 282 is formed. The low-k dielectric layer 282 has a dielectric constant smaller than that of silicon oxide, which is about 3.9. For example, the low-k dielectric layer 282 may include a porous organosilicate thin film (e.g., SiCOH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), boron carbonitride, spin-on silicon based polymeric dielectrics, or combinations thereof. The hard mask 284 is deposited on the low-k dielectric layer 282. The hard mask 284 may be a single-layer structure of a dual-layer structure. The hard mask 284 may be formed of aluminum oxide, silicon oxide, silicon nitride, silicon carbonitride, silicon oxycarbide, silicon oxynitride, silicon oxycarbonitride, other suitable materials, or combinations thereof.

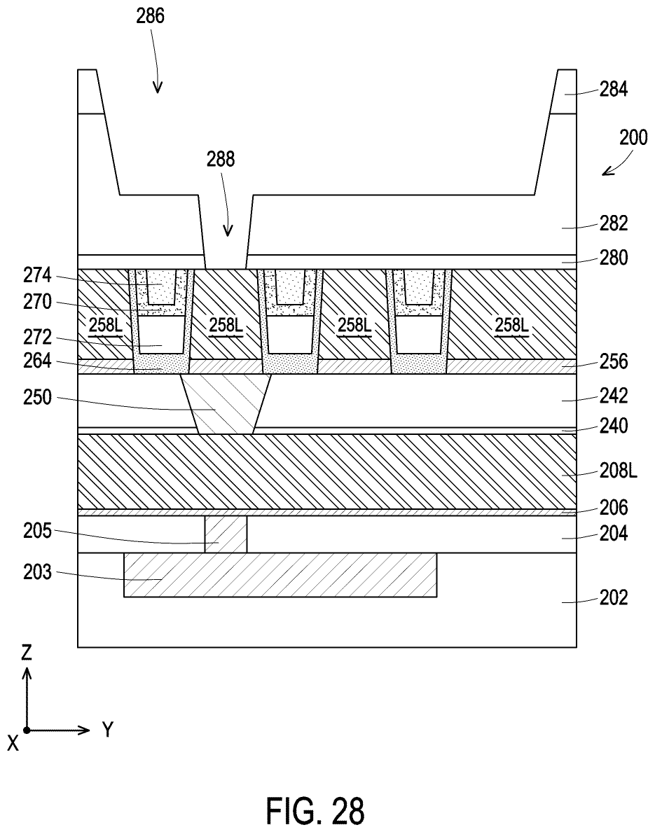

Referring to FIG. 28, trench opening 286 and via opening 288 are formed through one or more photolithography processes and etching processes. In some embodiments, forming the openings includes patterning the hard mask 284 in a first etching process, removing a top portion of the dielectric layer 282 in a second etching process to form the trench opening 286. The second etching process is implemented to partially etch the dielectric layer 282, such as by controlling the etching duration. During the second etching process, the dielectric layer 282 within the region defined by the trench opening 286 is only recessed but not completely through the dielectric layer 282. The dielectric layer 282 is further etched through the trench opening 286 by a third etching process to form the via opening 288. The third etching process is designed to selectively etch the dielectric layer 282 while the second ESL 280 substantially remains intact. The third etching process extends the via opening 288 downwardly, reaching the second ESL 280. The formation of the via opening 288 may also be assisted by photoresist for defining patterns. Photoresist is then removed in a suitable process such as resist stripping or plasma ashing. A fourth etching process is subsequently applied to open the second ESL 280. After the fourth etching process, both the trench opening 286 for a metal line and the via opening 288 for a via are collectively formed in the dielectric layer 282. The trench opening 286 is formed in the upper portion of the dielectric layer 282 and the via opening 288 is formed in the lower portion of the dielectric layer 282.

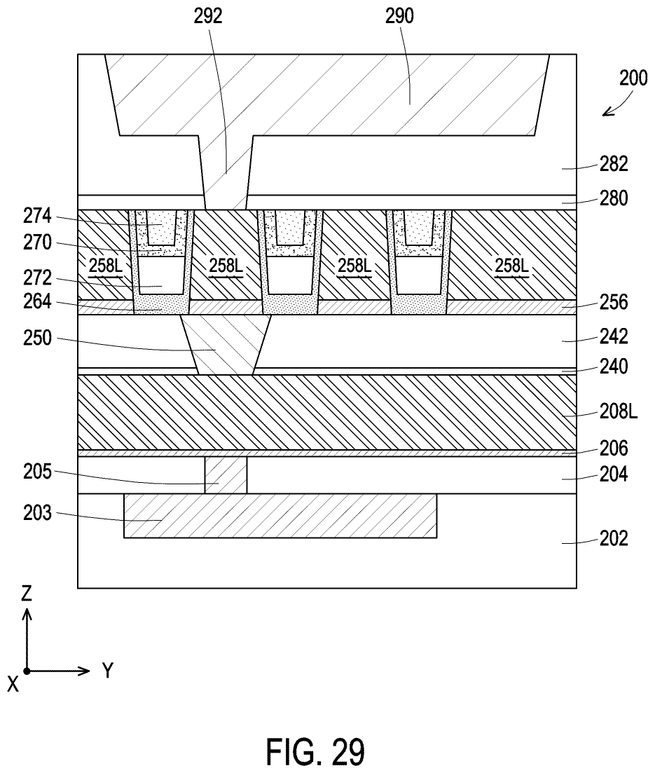

Referring to FIG. 29, a metal line 290 is formed in the trench opening 286 and a via 292 is formed in the via opening 288. In some embodiments, the metal line 290 and the via 292 are formed as a bulk metal layer by filling a conductive material in the trench opening 286 and the via opening 288. The conductive material may be deposited through suitable techniques such as an electroplating process, PVD, or other suitable methods. A diffusion barrier layer and an adhesion layer (not shown) may be deposited within the trench opening 286 and the via opening 288 prior to the deposition of the bulk metal layer. One advantageous feature of having the bulk metal layer formed in a damascene process is that some low-resistive conductive material (e.g., copper) may not otherwise be suitable for metal etching process may be deposited. In some embodiments, the conductive material is different from the metal used in the relatively narrower metal lines 208L and 258L underneath. In some embodiments, the metal lines 208L and 258L includes one or more noble metals as discussed above, while the bulk metal layer for metal line 290 and the via 292 includes one or more non-noble metals. For example, the bulk metal layer for metal line 290 and the via 292 may include copper (Cu), although other suitable materials such as tungsten (W), cobalt (Co), Nickel (Ni), aluminum (Al), combinations thereof, and/or the like, may alternatively be utilized. In some embodiments, the bulk metal layer also includes a noble metal but different from the one or more noble metals used in the metal lines 208L and 258L. For example, the bulk metal layer 248 may include Pt, while the metal lines 208L may include Rh or Au and the metal lines 258L may include Ru. Further, since the metal lines 208L and 258L are formed by direct patterning, the metal lines 208L and 258L each have a narrower top portion and a wider bottom portion; as a comparison, the metal line 290, the via 292, and the via 250 each have a wider top portion and a narrower bottom portion due to the formation by filling trenches in respective dielectric layers instead of a direct patterning. Compared with the via 250 and the via 292, in some embodiments, the via 250 is a barrier-free via as discussed above, while the via 292 includes a barrier-layer to prevent the metal element (e.g., copper) from diffusing into the dielectric layer 282.

Although not intended to be limiting, one or more embodiments of the present disclosure provide many benefits to a semiconductor structure and the formation thereof. For example, the present disclosure provides a dielectric structure disposed between two adjacent metal lines and methods of forming the same. The dielectric structure includes a high-kappa dielectric material layer to facilitate heat dissipation. The dielectric structure also includes an air gap, thereby reducing the effective dielectric constant of the dielectric structure and parasitic capacitance of the semiconductor structure.

The present disclosure provides for many different embodiments. Semiconductor structures and methods of fabrication thereof are disclosed herein. In one exemplary aspect, the present disclosure is directed to a method. The method includes forming a metal layer over a substrate, patterning the metal layer to from first and second metal lines with a trench therebetween, depositing a sacrificial layer in a lower portion of the trench, forming a first dielectric layer on the sacrificial layer, after the forming of the first dielectric layer, selectively removing the sacrificial layer to form an air gap between the first and second metal lines, and depositing a second dielectric layer over the first dielectric layer and in an upper portion of the trench. In some embodiments, the metal layer includes a noble metal. In some embodiments, the second dielectric layer has a thermal conductivity not less than about 10 W/m·K. In some embodiments, the first dielectric layer is a porous dielectric layer, such that the sacrificial layer is decomposed into volatile compound that diffuses through the porous dielectric layer during the selectively removing of the sacrificial layer. In some embodiments, the method further includes before the forming of the sacrificial layer, depositing a capping layer. The air gap is vertically between the capping layer and the first dielectric layer. In some embodiments, the capping layer includes a thermal conductive material with a thermal conductivity not less than about 10 W/m. K. In some embodiments, the forming of the sacrificial layer includes depositing a polymer layer in the trench and over the first and second metal lines, planarizing the polymer layer, and etching back the polymer layer. In some embodiments, the method further includes prior to the forming of the metal layer, forming a dielectric layer over the substrate with a via through the dielectric layer. The via is directly under one of the first and second metal lines, and wherein the trench partially exposes a top surface of the via. In some embodiments, the method further includes after the depositing of the second dielectric layer, performing a planarization process to expose the first and second metal lines. In some embodiments, after the performing of the planarization process, a thickness measured form a top surface of the second dielectric layer to a bottom surface of the first dielectric layer is about 20% to about 50% of a thickness of the first and second metal lines.

In another exemplary aspect, the present disclosure is directed to a method. The method includes forming a metal layer over a substrate, patterning the metal layer to form a trench separating the metal layer into at least a first portion and a second portion, forming a capping layer extending along top and sidewall surfaces of the first and second portions of the metal layer, depositing a sustaining layer between the first and second portions of the metal layer to seal the trench to form an air gap, depositing a thermal conductive layer over the sustaining layer and over the first and second portions of the metal layer, the thermal conductive layer having a thermal conductivity not less than about 10 W/m·K, and performing a planarization process to partially remove the thermal conductive layer and expose the first and second portions of the metal layer. In some embodiments, the capping layer has a thermal conductivity not less than about 10 W/m·K. In some embodiments, the method further includes depositing a polymer layer over the capping layer and under the sustaining layer to partially fill the trench, and selectively removing the polymer layer after the depositing of the sustaining layer to form the air gap. In some embodiments, the selectively removing of the polymer layer includes decomposing the polymer layer into volatile compound that diffuses through the sustaining layer. In some embodiments, the metal layer includes a noble metal. In some embodiments, the thermal conductive layer is a diamond or a diamond-like carbon.

In yet another exemplary aspect, the present disclosure is directed to a semiconductor structure. The semiconductor structure includes a conductive via extending through a first dielectric layer, a first metal line over and in electrical contact with the conductive via, and a second metal line over the first dielectric layer and separated from the first metal line by a dielectric structure. A top surface of the dielectric structure is coplanar with top surfaces of the first and second metal lines. The dielectric structure includes a top liner extending between the first and second metal lines, a thermal conductive layer over the top liner, the top liner extending along bottom and sidewall surfaces of the thermal conductive layer, and an air gap confined by the top liner. In some embodiments, the semiconductor structure further includes a bottom liner extending between the first and second metal lines and in contact with the first dielectric layer, wherein the air gap is vertically between the bottom liner and the top liner. In some embodiments, the top liner is in contact with the bottom liner. In some embodiments, each of the first and second metal lines has a top width that is narrower than a bottom width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first dielectric layer over a device layer comprising a plurality of transistors;
a first metal line embedded in a first dielectric layer and in electrical coupling with one of the transistors;
a second dielectric layer over the first dielectric layer;
a via embedded in the second dielectric layer and in electrical coupling with the first metal line;
a third dielectric layer over the second dielectric layer;
a second metal line embedded in the third dielectric layer and in electrical coupling with the via;
a third metal line embedded in the third dielectric layer and laterally spaced apart from the second metal line; and
a thermal conductive structure disposed between opposing sidewalls of the second and third metal lines, wherein the thermal conductive structure includes:
a capping layer disposed on the opposing sidewalls of the second and third metal lines and a top surface of the second dielectric layer,
a thermal conductive layer with a thermal conductivity not less than 10 W/m·K, and
an air gap disposed between the capping layer and the thermal conductive layer.

2. The semiconductor structure of claim 1, wherein the thermal conductive structure further includes a sustaining layer disposed between the capping layer and the thermal conductive layer, wherein the air gap is positioned between the capping layer and the sustaining layer.

3. The semiconductor structure of claim 2, wherein the sustaining layer has a porous structure.

4. The semiconductor structure of claim 1, wherein top surfaces of the thermal conductive structure, the second metal line, and the third metal line are coplanar.

5. The semiconductor structure of claim 1, wherein the capping layer is formed of a thermal conductive material with a thermal conductivity not less than 10 W/m·K.

6. The semiconductor structure of claim 5, wherein the capping layer and the thermal conductive layer both include the thermal conductive material.

7. The semiconductor structure of claim 1, wherein the thermal conductive layer includes hexagonal boron nitride or aluminum nitride.

8. The semiconductor structure of claim 1, wherein a bottom surface of the capping layer interfaces with a top surface of the via.

9. The semiconductor structure of claim 1, wherein each of the first, second, and third metal lines includes a noble metal.

10. The semiconductor structure of claim 1, wherein the first metal line extends lengthwise in a first direction, the second and third metal lines extend lengthwise in a second direction different from the first direction.

11. A semiconductor structure, comprising:
a conductive via embedded in a first dielectric layer;
a second dielectric layer over the first dielectric layer;
a first metal line embedded in the second dielectric layer and in electrical coupling with the conductive via; and
a second metal line embedded in the second dielectric layer and separated from the first metal line by a dielectric structure,
wherein a top surface of the dielectric structure is coplanar with top surfaces of the first and second metal lines, and wherein the dielectric structure includes:
a capping layer extending between opposing sidewalls of the first and second metal lines,
a thermal conductive layer over the capping layer, and
an air gap between the capping layer and the thermal conductive layer.

12. The semiconductor structure of claim 11, further comprising:
a sustaining layer between the capping layer and the thermal conductive layer, wherein the air gap is between the capping layer and the sustaining layer.

13. The semiconductor structure of claim 12, wherein the sustaining layer has a porous structure.

14. The semiconductor structure of claim 12, wherein the sustaining layer separates the thermal conductive layer from the capping layer.

15. The semiconductor structure of claim 11, further comprising:
a glue layer between the first metal line and the conductive via, wherein a horizontal portion of the capping layer has a thickness greater than the glue layer.

16. The semiconductor structure of claim 11, wherein each of the first and second metal lines has a top width that is narrower than a bottom width.

17. A method, comprising:
forming a metal layer over a substrate;
patterning the metal layer to from first and second metal lines with a trench therebetween;
conformally depositing a capping layer in the trench;
depositing a sacrificial layer in the trench and over the capping layer;
recessing the sacrificial layer;
forming a sustaining layer on the sacrificial layer;
after the forming of the sustaining layer, removing the sacrificial layer to form an air gap between the first and second metal lines; and
depositing a thermal conductive layer over the sustaining layer and in an upper portion of the trench.

18. The method of claim 17, wherein the thermal conductive layer has a thermal conductivity not less than 10 W/m·K.

19. The method of claim 17, wherein the metal layer includes a noble metal.

20. The method of claim 17, wherein the sustaining layer has a porous structure, such that the sacrificial layer is decomposed into volatile compound that diffuses through the porous structure during the removing of the sacrificial layer.
